(19) United States
(12) Patent Application Publication
(10) Pub. No.: US 2024/0056051 A1
(43) Pub. Date: Feb. 15, 2024

(54) ACOUSTIC WAVE DEVICE

(71) Applicant: Murata Manufacturing Co., Ltd., Nagaokakyo-shi (JP)

(72) Inventors: Yutaka KISHIMOTO, Nagaokakyo-shi (JP); Masashi OMURA, Nagaokakyo-shi (JP); Katsumi SUZUKI, Nagaokakyo-shi (JP); Kazunori INOUE, Nagaokakyo-shi (JP)

(21) Appl. No.: 18/383,924

(22) Filed: Oct. 26, 2023

Related U.S. Application Data
(63) Continuation of application No. PCT/JP2022/004691, filed on Feb. 7, 2022.

(30) Foreign Application Priority Data
Apr. 28, 2021 (JP) 2021-076296

(51) Int. Cl. H03H 9/17; H03H 9/13

(52) U.S. Cl. CPC H03H 9/17; H03H 9/131

(57) ABSTRACT

An acoustic wave device includes a first layer including a support substrate, a second layer on the first layer and including a piezoelectric film, and a first excitation electrode on the second layer. A cavity is between the first and second layers, and the first excitation electrode at least partially overlaps the cavity in a stacking direction of the first and second layers. A surface roughness of a major surface of the first layer facing the cavity is different from a surface roughness of a major surface of the second layer facing the cavity.

### CROSS REFERENCE TO RELATED APPLICATIONS

This application claims the benefit of priority to Japanese Patent Application No. 2021-076296 filed on Apr. 28, 2021 and is a Continuation Application of PCT Application No. PCT/JP2022/004691 filed on Feb. 7, 2022. The entire contents of each application are hereby incorporated herein by reference.

### BACKGROUND OF THE INVENTION

### 1. Field of the Invention

The present invention relates to an acoustic wave device including a cavity below or under a piezoelectric film.

### 2. Description of the Related Art

Acoustic wave devices have been known in which a cavity is provided under a piezoelectric film. For example, in International Publication No. 2011/052551, drive electrodes are provided on the upper and lower surfaces of a piezoelectric film. A cavity is provided under this piezoelectric film. An acoustic wave device is thus configured having a membrane structure.

### SUMMARY OF THE INVENTION

In an acoustic wave device having a membrane structure in which a cavity is provided under a piezoelectric film, characteristics may be degraded by excitation of unnecessary waves.

Preferred embodiments of the present invention provide acoustic wave devices with characteristics that are less likely to be degraded.

An acoustic wave device according to a preferred embodiment of the present invention includes a first layer including a support substrate, a second layer on the first layer and including a piezoelectric film, and an excitation electrode on the second layer, wherein a cavity is between the first layer and the second layer, and the excitation electrode at least partially overlaps the cavity in a stacking direction of the first layer and the second layer, and a surface roughness of a major surface of the first layer facing the cavity is different from a surface roughness of a major surface of the second layer facing the cavity.

Preferred embodiments of the present invention provide acoustic wave devices with characteristics that are less likely to be degraded.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B are a plan view and an elevational cross-sectional view of an acoustic wave device according to a first preferred embodiment of the present invention.

FIGS. 2A to 2D are elevational cross-sectional views for explaining a method for manufacturing an acoustic wave device according to the first preferred embodiment of the present invention.

FIGS. 3A to 3C are elevational cross-sectional views for explaining the method for manufacturing an acoustic wave device according to the first preferred embodiment of the present invention.

FIGS. 4A to 4C are elevational cross-sectional views for explaining the method for manufacturing an acoustic wave device according to the first preferred embodiment of the present invention.

FIGS. 5A to 5C are elevational cross-sectional views for explaining the method for manufacturing an acoustic wave device according to the first preferred embodiment of the present invention.

FIG. 6 is an elevational cross-sectional view of an acoustic wave device according to a second preferred embodiment of the present invention.

FIGS. 7A and 7B are an elevational cross-sectional view of an acoustic wave device and a schematic plan view showing an electrode structure according to a third preferred embodiment of the present invention.

FIG. 8 is an elevational cross-sectional view of an acoustic wave device according to a fourth preferred embodiment of the present invention.

FIG. 9 is an elevational cross-sectional view of an acoustic wave device according to a fifth preferred embodiment of the present invention.

FIGS. 10A and 10B are an elevational cross-sectional view and a plan view of an acoustic wave device according to a modification of the fifth preferred embodiment of the present invention.

FIG. 11 is an elevational cross-sectional view of an acoustic wave device according to a sixth preferred embodiment of the present invention.

FIG. 12 is an elevational cross-sectional view of an acoustic wave device according to a seventh preferred embodiment of the present invention.

### DETAILED DESCRIPTION OF THE PREFERRED EMBODIMENTS

Hereinafter, the present invention will be clarified by describing specific preferred embodiments of the present invention with reference to the drawings.

It should be noted that the preferred embodiments described in the present specification are exemplary and partial replacement or combination of components between different preferred embodiments is possible.

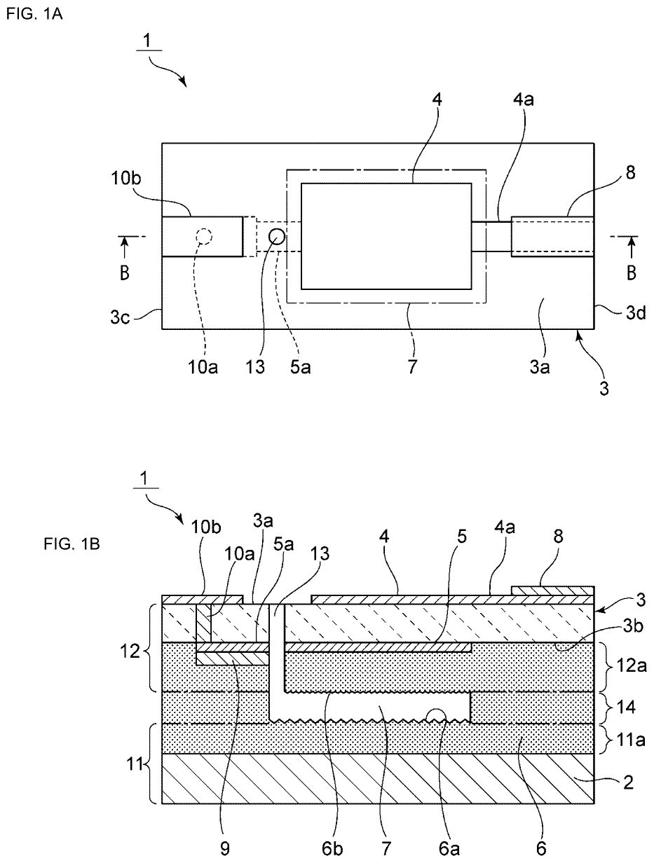

FIGS. 1A and 1B are a plan view and an elevational cross-sectional view taken along line B-B in FIG. 1A, showing an acoustic wave device according to a first preferred embodiment of the present invention.

In an acoustic wave device 1, a second layer 12 including a piezoelectric film 3 is stacked above a first layer 11 including a support substrate 2. A first excitation electrode 4, that is, an upper electrode is provided on the second layer 12.

The support substrate 2 is made of silicon. However, the material of the support substrate 2 is not particularly limited. Various insulating and semiconductor materials can be used.

The piezoelectric film 3 is made of piezoelectric single crystal. Such a piezoelectric single crystal can be lithium tantalate, lithium niobate, quartz, or the like. In this preferred embodiment, the piezoelectric film 3 is made of lithium tantalate, for example. Note that the piezoelectric film 3 only needs to include a piezoelectric material and does not necessarily need to be made of piezoelectric single crystal.

The piezoelectric film 3 includes a first major surface 3a and a second major surface 3b located on a support substrate 2 side. A second excitation electrode 5, that is, a lower electrode is provided on the second major surface 3b. The first excitation electrode 4 and the second excitation electrode 5 have an overlapping portion with the piezoelectric film 3 interposed therebetween. This overlapping portion defines and functions as an excitation region.

The first excitation electrode 4 includes an extended portion 4a. The extended portion 4a is extended toward an edge 3d on the first major surface 3a. This extended portion 4a has a width narrower than that of the first excitation electrode 4 in the excitation region, for example. A second layer wiring line 8 is stacked on the extended portion 4a.

The second excitation electrode 5 has an extended portion 5a. The extended portion 5a extends from the excitation region toward an edge 3c. The edge 3c is on the opposite side to the edge 3d.

The extended portion 5a has a width narrower than that of the second excitation electrode 5 in the excitation region. A through-hole 13 to be described later is positioned in the middle of the extended portion 5a. A second layer wiring line 9 is stacked on the extended portion 5a.

A through-hole electrode 10a penetrating the piezoelectric film 3 is connected to the extended portion 5a. A terminal electrode 10b is provided on the first major surface 3a so as to be connected to the through-hole electrode 10a. An alternating-current voltage can be applied from outside through the second layer wiring line 8 and the terminal electrode 10b, thus exciting the excitation region in the piezoelectric film 3.

The first and second excitation electrodes 4 and 5, the second layer wiring lines 8 and 9, the through-hole electrode 10a, and the terminal electrode 10b are made of an appropriate metal or alloy. Examples of such a material include Al, Pt, Cu, W, Mo, alloys including these metals, and the like. These electrodes and wiring lines may be made of a multilayer body of a plurality of metal films.

An intermediate layer 6 is provided between the support substrate 2 and the piezoelectric film 3. The intermediate layer 6 can be made of an appropriate insulating material. Such an insulating material can be silicon oxide, silicon oxynitride, alumina, or the like. In this preferred embodiment, the intermediate layer 6 is made of silicon oxide, for example.

The intermediate layer 6 is provided with a cavity 7. The cavity 7 overlaps the first excitation electrode 4 in the stacking direction of the first layer 11 and the second layer 12, as shown in FIG. 1B. Note that, as shown in FIG. 1A, it is preferable that the entire rectangular first excitation electrode 4 overlaps the cavity 7 shown by the dashed-dotted line. When the first excitation electrode 4 and the extended portion 4a are considered to be an excitation electrode as a whole, the excitation electrode only needs to partially overlap the cavity 7.

The through-hole 13 is connected to the cavity 7. The through-hole 13 extends from the first major surface 3a of the piezoelectric film 3 toward the first layer 11 side before reaching the cavity 7. Note that the through-hole 13 does not need to be provided.

As described above, the through-hole 13 may penetrate the extended portion 5a or does not need to penetrate the extended portion 5a. In other words, the through-hole 13 may be provided in a region where the extended portion 5a is not provided. When the through-hole 13 penetrates the extended portion 5a, it acts on the excitation, making it possible to improve wave confinement efficiency and spurious.

The intermediate layer 6 includes a first intermediate layer 11a defining a portion of the first layer 11, a second intermediate layer 12a defining a portion of the second layer 12, and a third intermediate layer 14 located between the first and second intermediate layers 11a and 12a. The cavity 7 is provided in the third intermediate layer 14. This means that the cavity 7 is provided between the first layer 11 and the second layer 12. The first intermediate layer 11a is provided on a major surface of the support substrate 2 on the cavity 7 side. The second intermediate layer 12a is provided on the major surface 3b of the piezoelectric film 3 on the cavity 7 side.

In this preferred embodiment, the first intermediate layer 11a, the second intermediate layer 12a, and the third intermediate layer 14 are integrally formed of silicon oxide. The first to third intermediate layers 11a, 12a, and 14 may be made of the same material or different materials. The major surface 6a of the first layer 11 facing the cavity 7 has a surface roughness Ra larger than a surface roughness Ra of a major surface 6b of the second layer 12 facing the cavity 7. The surface roughness Ra here is the arithmetic average roughness Ra defined in JIS B0601. In this preferred embodiment, the value of the surface roughness Ra of the major surface 6a is larger than the value of the surface roughness Ra of the major surface 6b. The surface roughness Ra can be calculated by surface morphology measurement using a scanning probe microscope (SPM), a scanning electron microscope (SEM), or the like.

The second major surface 6b may be a smooth surface, for example, rather than a rough surface as long as the surface roughness Ra of the first major surface 6a is different from the surface roughness Ra of the second major surface 6b.

It is preferable that, as in this preferred embodiment, both major surfaces 6a and 6b have the surface roughness Ra larger than a surface roughness Ra of the first major surface 3a of the second layer 12 on the side where the first excitation electrode 4 is provided. This enables, as will be described later, unnecessary waves to be scattered more effectively, thus preventing characteristic degradation.

In the acoustic wave device 1, the surface roughness Ra of the major surface 6a is larger than the surface roughness Ra of the major surface 6b. Therefore, unnecessary waves can be effectively scattered. This can prevent characteristic degradation of the acoustic wave device 1.

It is preferable that the surface roughness Ra of the major surfaces 6a and 6b is more than or equal to about 0.5 nm, for example. It is more preferable that the surface roughness Ra of the major surfaces 6a and 6b is more than or equal to about 1 nm, for example. This enables unnecessary waves to be suppressed more effectively. The upper limit of the surface roughness Ra is such that it does not exceed the film thickness of the first intermediate layer 11a or the second intermediate layer 12a. Otherwise, the support substrate 2 and the second excitation electrode 5 may be damaged.

In the acoustic wave device 1, the major surfaces 6a and 6b are both major surfaces of the intermediate layer 6, but the major surface 6b may be the major surface of the piezoelectric film 3 and the major surface 6a may be the major surface of the support substrate 2. When the major surface 6b is the major surface of the intermediate layer 6, it is easier to achieve the effect of reducing damage on the piezoelectric film 3 by the chemical used in the process of manufacturing the acoustic wave device 1, compared to the case where the major surface 6b is the major surface of the piezoelectric film 3. When the major surface 6a is the major surface of the intermediate layer 6, on the other hand, it is easier to achieve the effect of eliminating the need for alignment when joining the piezoelectric film 3 and the support substrate 2 in the process of manufacturing the acoustic wave device 1, compared to the case where the major surface 6a is the major surface of the support substrate 2.

A method for roughening the major surfaces 6a and 6b is not particularly limited. Etching methods such as reactive ion etching (RIE) and dry etching, laser polishing, and the like can be used.

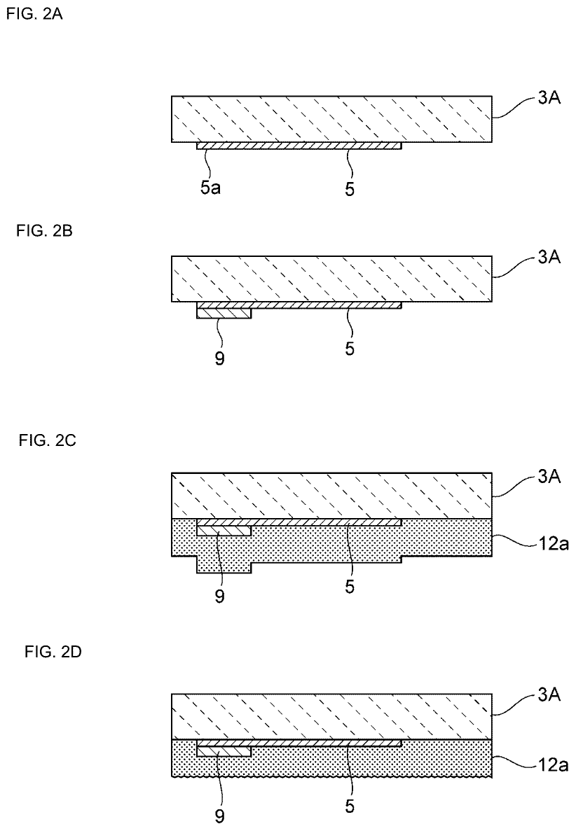

Next, a non-limiting example of a method for manufacturing the acoustic wave device 1 will be described with reference to FIGS. 2A to 2D, FIGS. 3A to 3C, FIGS. 4A to 4C, and FIGS. 5A to 5C.

As shown in FIG. 2A, a second excitation electrode 5 and an extended portion 5a are formed on one side of a piezoelectric substrate 3A made of piezoelectric single crystal. Then, a second layer wiring line 9 is formed on the extended portion 5a. A method for forming the second excitation electrode 5 and the second layer wiring line 9 is not particularly limited, but a lift-off method using photolithography or the like can be used. The second excitation electrode 5 and the extended portion 5a may be formed by sputtering or the like.

Next, as shown in FIG. 2C, a second intermediate layer 12a is formed by depositing silicon oxide. Protrusions of the second intermediate layer 12a in portions overlapping the second excitation electrode 5 and the second layer wiring line 9 are removed by etching, polishing, or the like. As shown in FIG. 2D, the lower surface of the second intermediate layer 12a is thus planarized and roughened. By controlling the etching conditions, the surface roughness of the lower surface of the second intermediate layer 12a, that is, a major surface 6b to be described later can be controlled.

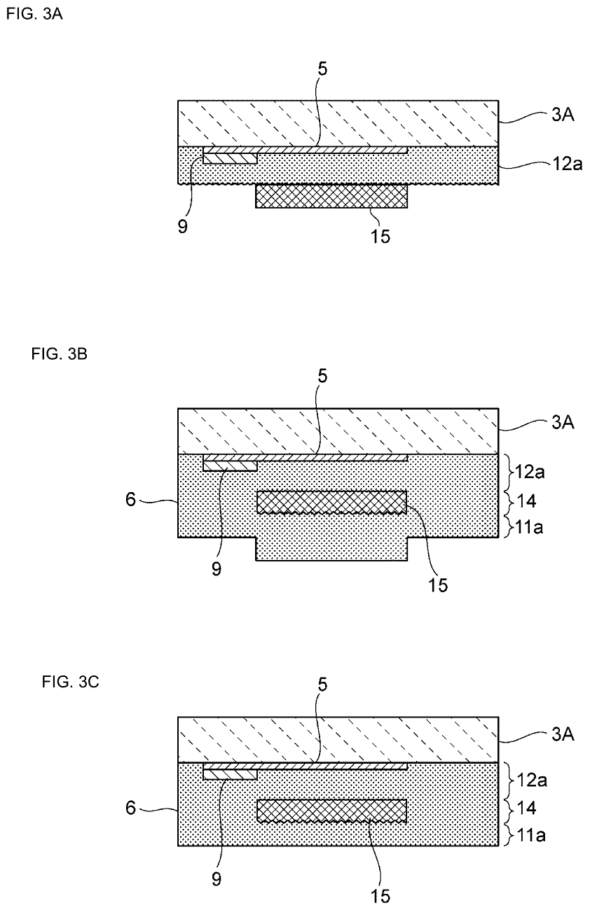

As shown in FIG. 3A, a sacrificial layer 15 is then stacked on the lower surface of the second intermediate layer 12a. The sacrificial layer 15 is made of a material that can be removed with an etchant to be described later. Such a material is not particularly limited, but the sacrificial layer 15 is made of ZnO in this preferred embodiment. The sacrificial layer 15 can be formed by an appropriate thin film forming method such as sputtering.

The sacrificial layer 15 is provided as shown in FIG. 3A. A lower surface of the sacrificial layer 15 is then roughened by etching or the like. By controlling the etching conditions, the surface roughness of the lower surface of the sacrificial layer 15 can be made different from the surface roughness of an upper surface of the sacrificial layer 15, that is, the lower surface of the second intermediate layer 12a.

As shown in FIG. 3B, silicon oxide is then further continuously deposited to form an intermediate layer 6. Thus, a third intermediate layer 14 and a first intermediate layer 11a are integrally stacked on the second intermediate layer 12a. Below the portion where the sacrificial layer 15 is provided, the silicon oxide film protrudes downward by the thickness of the sacrificial layer 15. As shown in FIG. 3C, this protrusion is removed for planarization. This planarization can be performed by etching, CMP polishing, or the like.

In this preferred embodiment, as shown in FIG. 3B, the surface roughness of the lower surface of the sacrificial layer 15 is larger than the surface roughness of the upper surface. This surface roughness of the lower surface of the sacrificial layer 15 eventually corresponds to the surface roughness of a major surface 6a facing a cavity 7. The surface roughness of the upper surface of the sacrificial layer 15 corresponds to the surface roughness of a major surface 6b.

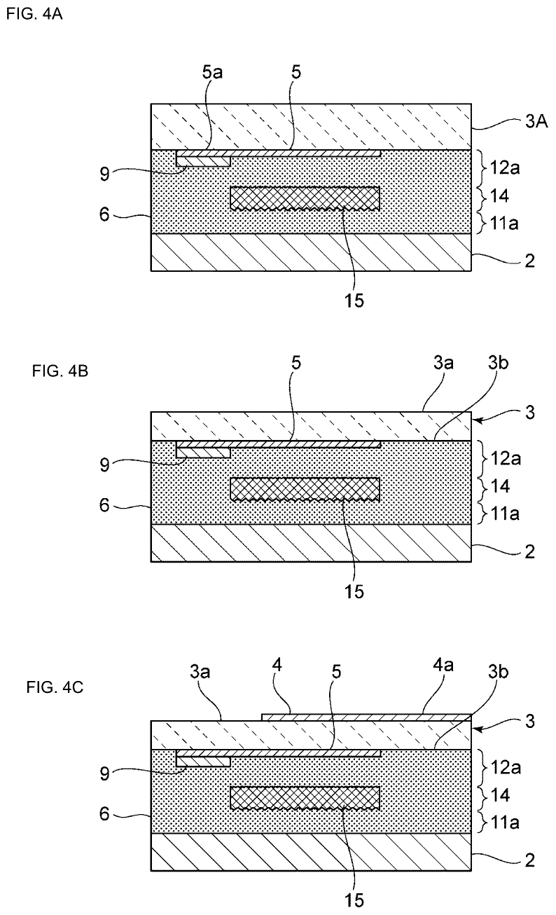

Next, as shown in FIG. 4A, the support substrate 2 is bonded to the intermediate layer 6.

The piezoelectric substrate 3A is then ground by CMP polishing or by using a grinder. A thin piezoelectric film 3 is thus formed as shown in FIG. 4B.

As shown in FIG. 4C, a first excitation electrode 4 and an extended portion 4a are then provided. The first excitation electrode 4 and the extended portion 4a can be formed in the same manner as, for example, the second excitation electrode 5.

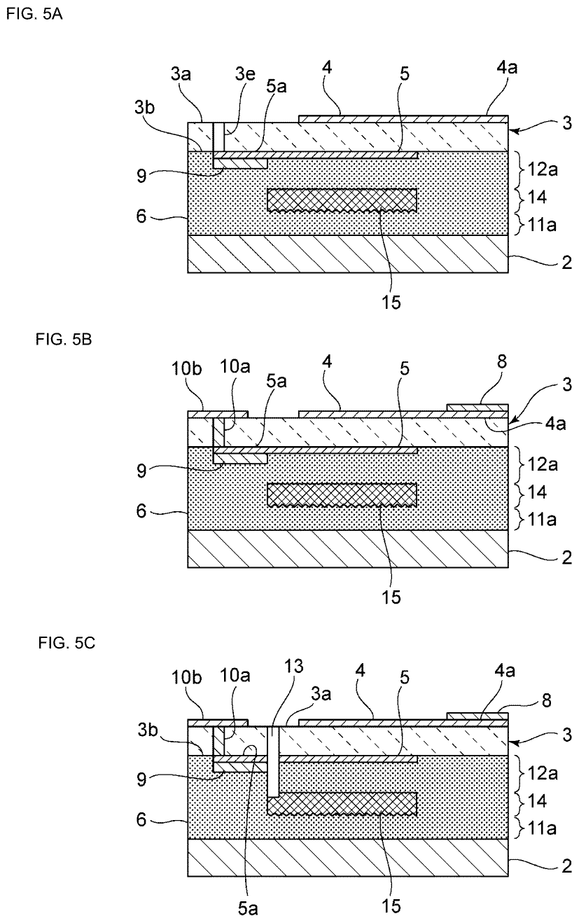

As shown in FIG. 5A, a through-hole 3e is provided in the piezoelectric film 3. Thereafter, as shown in FIG. 5B, a through-hole electrode 10a is formed to fill the through-hole 3e, and a terminal electrode 10b is further formed. A second layer wiring line 8 is also formed.

As shown in FIG. 5C, a through-hole 13 is then provided.

Next, an etchant for removing the sacrificial layer 15 is injected through the through-hole 13, thus dissolving and removing the material forming the sacrificial layer 15. The acoustic wave device 1 shown in FIG. 1B can be thus obtained.

In the acoustic wave device 1 according to the first preferred embodiment, the surface roughness of the major surface 6a is larger than the surface roughness of the major surface 6b, thus making it easier to reduce the time taken to remove the sacrificial layer 15 with the etchant. Therefore, damage caused by the etchant on the major surface 6b is reduced, thus also achieving the effect of preventing characteristic degradation.

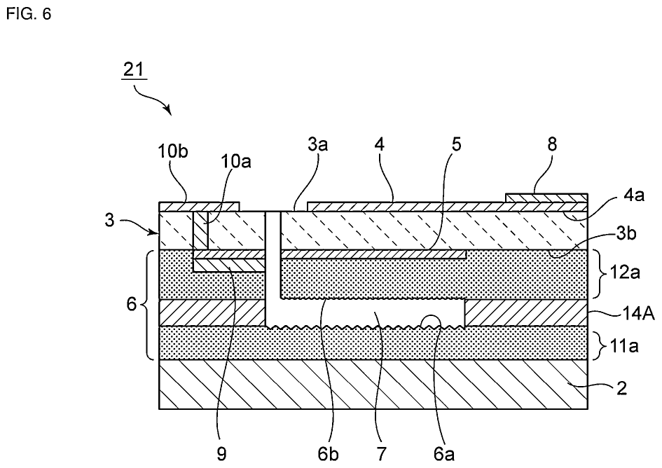

FIG. 6 is an elevational cross-sectional view of an acoustic wave device according to a second preferred embodiment of the present invention. In an acoustic wave device 21, a material forming a third intermediate layer 14A is different from a material forming a first intermediate layer 11a and a second intermediate layer 12a in an intermediate layer 6. That is, the third intermediate layer 14A made of a different material is provided between the first intermediate layer 11a and the second intermediate layer 12a. In the intermediate layer 6, the first intermediate layer 11a, the second intermediate layer 12a, and the third intermediate layer 14A may be made of different materials. The first intermediate layer 11a and the second intermediate layer 12a may also be formed of different materials.

In the acoustic wave device 21, again, the surface roughness of major surfaces 6a and 6b facing a cavity 7 is the same as that in the acoustic wave device 1. Therefore, unnecessary waves can be scattered and characteristic degradation can be prevented.

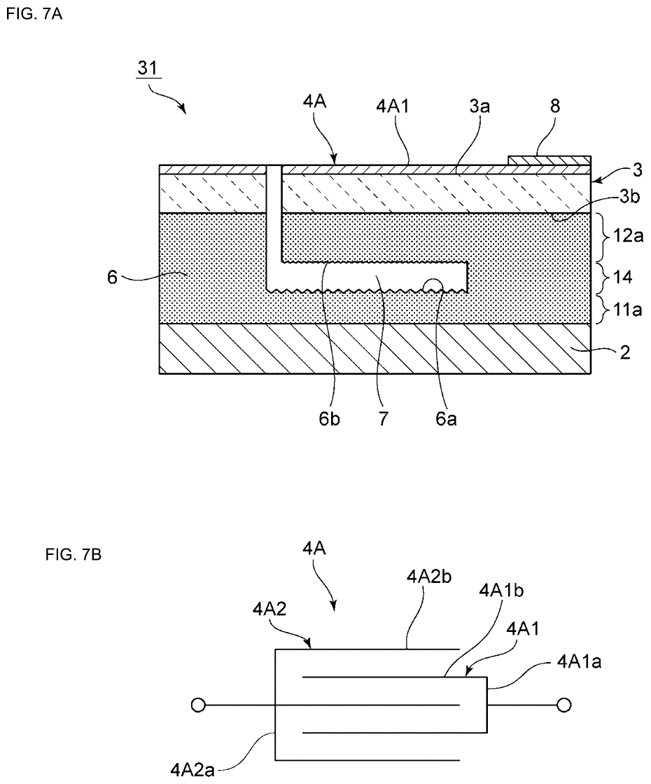

FIGS. 7A and 7B are an elevational cross-sectional view of an acoustic wave device and a schematic plan view showing an electrode structure according to a third preferred embodiment of the present invention. In an acoustic wave device 31, a first excitation electrode 4A is provided on a piezoelectric film 3. The first excitation electrode 4A is an IDT electrode having a first comb-shaped electrode 4A1 and a second comb-shaped electrode 4A2 as shown in FIG. 7B. Specifically, the first comb-shaped electrode 4A1 includes a first busbar 4A1a and a plurality of first electrode fingers 4A1b whose base ends are connected to the first busbar 4A1a. The second comb-shaped electrode 4A2 includes a second busbar 4A2a facing the first busbar 4A1a, and a plurality of second electrode fingers 4A2b whose base ends are connected to the second busbar 4A2a. The plurality of first electrode fingers 4A1b and the plurality of second electrode fingers 4A2b interdigitate with each other. As in the acoustic wave device 31, the excitation electrode provided on the piezoelectric film 3 may be an IDT electrode according to a preferred embodiment of the present invention.

In the acoustic wave device 31, again, the surface roughness of major surfaces 6a and 6b facing a cavity 7 is the same as that in the acoustic wave device 1 according to the first preferred embodiment. Therefore, unnecessary waves can be scattered and characteristic degradation can be effectively prevented.

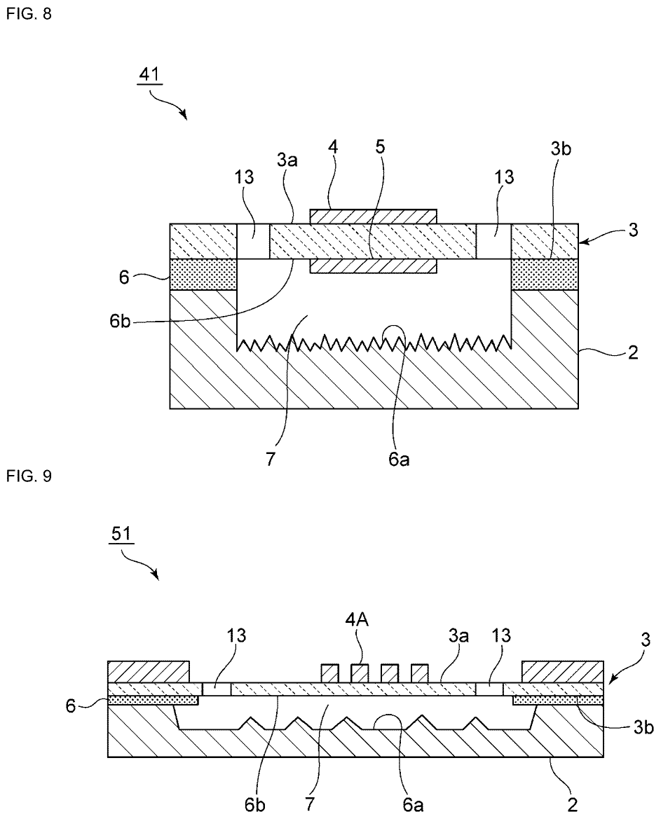

FIG. 8 is an elevational cross-sectional view of an acoustic wave device according to a fourth preferred embodiment of the present invention. In an acoustic wave device 41, again, major surfaces 6a and 6b facing a cavity 7 are different from each other in surface roughness. Therefore, unnecessary waves can be scattered and characteristic degradation can be effectively prevented. Specifically, the major surface 6a is provided with a plurality of protrusions that protrude from the major surface 6a toward the cavity 7. Here, in the acoustic wave device 41, the plurality of protrusions provided on the major surface 6a include protrusions which differ in height (size in the stacking direction of the support substrate 2 and the piezoelectric film 3). This makes it easier to prevent the piezoelectric film 3 from sticking to the major surface 6a when bending toward the cavity 7 side.

The plurality of protrusions provided on the major surface 6a have a tapered shape whose width becomes narrower toward the cavity 7 side. Specifically, in plan view in the stacking direction of the support substrate 2 and the piezoelectric film 3, the plurality of protrusions are arranged in dots. The plurality of protrusions provided on the major surface 6a have sharp end portions on the cavity 7 side. In other words, even when the piezoelectric film 3 bends and sticks to the major surface 6a, the vibration of the piezoelectric film 3 is less likely to be inhibited. Thus, characteristic degradation of the acoustic wave device 41 can be prevented.

In plan view in the stacking direction of the support substrate 2 and the piezoelectric film 3, the total area of areas where the end portions of the plurality of protrusions on the cavity 7 side and the piezoelectric film 3 overlap each other may be less than about 5% of the area of the piezoelectric film 3 that overlaps the cavity 7 in plan view in the stacking direction of the support substrate 2 and the piezoelectric film 3, for example. In this case, the characteristic degradation of the acoustic wave device 41 can be more surely and more easily prevented.

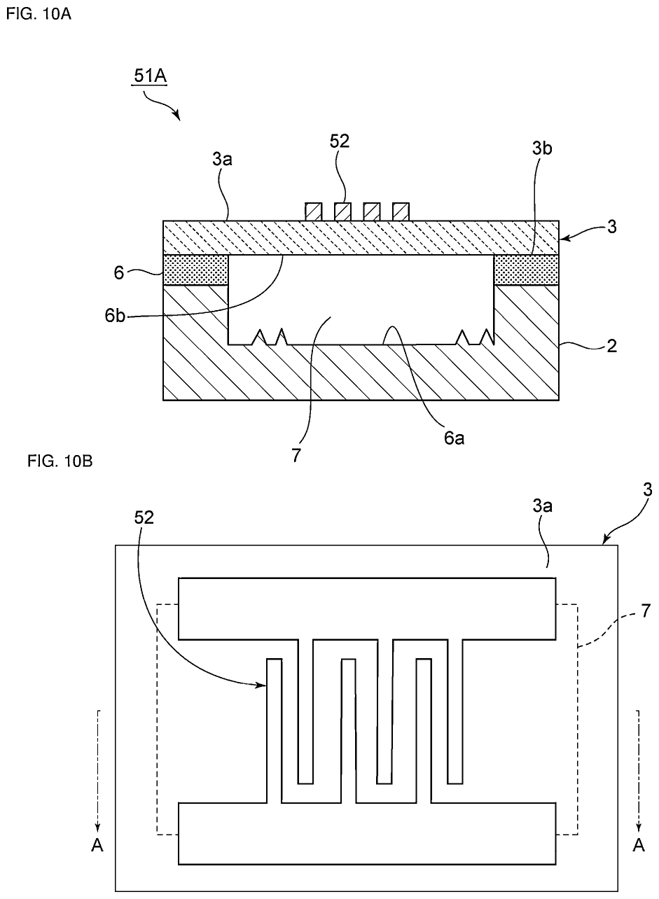

FIG. 9 is an elevational cross-sectional view of an acoustic wave device according to a fifth preferred embodiment of the present invention. In an acoustic wave device 51, again, major surfaces 6a and 6b facing a cavity 7 are different from each other in surface roughness. Therefore, unnecessary waves can be scattered and characteristic degradation can be effectively prevented. In the acoustic wave device 51, adjacent protrusions among a plurality of protrusions provided on the major surface 6a may be provided with a predetermined distance therebetween. This makes it easier to prevent the piezoelectric film 3 from sticking to the major surface 6a when bending toward the cavity 7 side. Specifically, for example, a flexible portion of the piezoelectric film 3 and a region between adjacent protrusions overlap in plan view in the stacking direction of the support substrate 2 and the piezoelectric film 3. This can prevent the piezoelectric film 3 from sticking to the major surface 6a of the support substrate 2 even when the piezoelectric film 3 bends. In that case, the flexible portion of the piezoelectric film 3 is sandwiched between the protrusions in plan view in the stacking direction of the support substrate 2 and the piezoelectric film 3. This can make the piezoelectric film 3 less flexible. When adjacent protrusions are provided at a predetermined distance from each other, adjusting the positions of the protrusions makes it easier to prevent the piezoelectric film 3 from sticking to the major surface 6a. Note that, as shown in FIG. 9, there may be locations where the distances between adjacent protrusions are different.

When a functional electrode is an IDT electrode 52 as in an acoustic wave device 51A shown in FIGS. 10A and 10B, no protrusions may be provided in a location that overlaps an intersecting region of the IDT electrode 52 (region where first and second electrode fingers of the IDT electrode 52 overlap when viewed in the direction in which the electrode fingers are arranged) and protrusions may be provided in a location that does not overlap the intersecting region in plan view in the stacking direction of the support substrate 2 and the piezoelectric film 3. A portion of the piezoelectric film 3 that overlaps the intersecting region in plan view in the stacking direction of the support substrate 2 and the piezoelectric film 3 is more flexible than other portions. Therefore, the piezoelectric film 3 can be more easily prevented from sticking to the major surface 6a by providing no protrusions in the location that overlaps the intersecting region and providing protrusions in other locations.

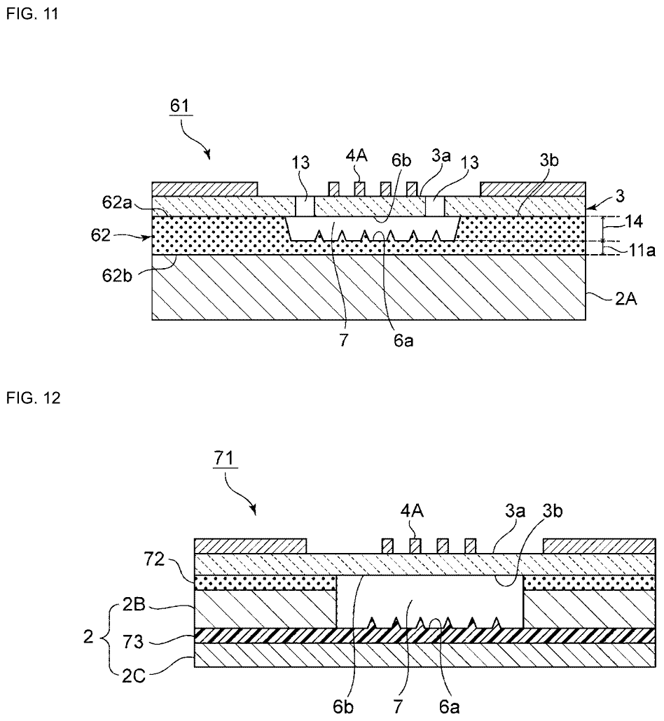

FIG. 11 is an elevational cross-sectional view of an acoustic wave device according to a sixth preferred embodiment of the present invention. In an acoustic wave device 61, again, major surfaces 6a and 6b facing a cavity 7 are different from each other in surface roughness Ra. Here, the surface roughness Ra of the major surface 6a is larger than the surface roughness Ra of the major surface 6b.

In the acoustic wave device 61, an intermediate layer 62 is provided between a support substrate 2A and a piezoelectric film 3. This intermediate layer 62 is provided with a recess that is open toward the piezoelectric film 3 side, thereby forming a cavity 7. The major surface 6a is a major surface of the material forming the intermediate layer 62, which faces the cavity 7. The major surface 6b is a major surface of the piezoelectric film 3 facing the cavity 7, that is, a second major surface 3b of the piezoelectric film 3. Therefore, as in the first preferred embodiment, a first intermediate layer 11a is between the major surface 62b of the intermediate layer 62 on the support substrate 2A side and the major surface 6a corresponding to the lower surface of the cavity 7. A third intermediate layer 14 is between the major surface 62a of the intermediate layer 62 on the piezoelectric film 3 side and the major surface 6a that is the lower surface of the cavity 7.

The material of the intermediate layer 62 is not particularly limited, but a bonding material made of an inorganic material, a synthetic resin, or the like can be used as in the above preferred embodiments.

FIG. 12 is an elevational cross-sectional view of an acoustic wave device according to a seventh preferred embodiment of the present invention. In a support substrate 2 of an acoustic wave device 71, a second support substrate layer 2B is stacked on a third support substrate layer 2C with a support substrate intermediate layer 73 interposed therebetween. An intermediate layer 72 is provided between the support substrate 2 and a piezoelectric film 3. A cavity 7 is provided so as to penetrate the intermediate layer 72 and the second support substrate layer 2B. Therefore, a major surface 6a facing the cavity 7 is an upper surface of the support substrate intermediate layer 73. On the other hand, a major surface 6b facing the cavity 7 is a second major surface 3b of the piezoelectric film 3.

In this preferred embodiment, again, the surface roughness Ra of the major surface 6a is different from the surface roughness Ra of the major surface 6b. More specifically, the surface roughness Ra of the major surface 6a is larger than the surface roughness Ra of the major surface 6b.

As described above, the support substrate 2 may have a structure in which the second support substrate layer 2B is stacked on the third support substrate layer 2C with the support substrate intermediate layer 73 interposed therebetween. Note that the support substrate intermediate layer 73 is made of an appropriate material such as a synthetic resin or an inorganic material.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first layer including a support substrate;
a second layer on the first layer and including a piezoelectric film; and
an excitation electrode on the second layer; wherein
a cavity is between the first layer and the second layer, and the excitation electrode at least partially overlaps the cavity in a stacking direction of the first layer and the second layer; and
a surface roughness of a major surface of the first layer facing the cavity is different from a surface roughness of a major surface of the second layer facing the cavity.

2. The acoustic wave device according to claim 1, wherein the surface roughness of the major surface of the first layer facing the cavity is larger than the surface roughness of the major surface of the second layer facing the cavity.

3. The acoustic wave device according to claim 1, wherein a through-hole penetrates the second layer and reaches the cavity.

4. The acoustic wave device according to claim 1, wherein the surface roughness of the major surface of the first layer facing the cavity and the surface roughness of the major surface of the second layer facing the cavity are both larger than a surface roughness of a major surface of the second layer on which the excitation electrode is provided.

5. The acoustic wave device according to claim 1, wherein the second layer further includes a second intermediate layer provided on a major surface of the piezoelectric film on a cavity side.

6. The acoustic wave device according to claim 5, wherein the first layer further includes a first intermediate layer provided on a major surface of the support substrate on a cavity side.

7. The acoustic wave device according to claim 6, wherein the first intermediate layer and the second intermediate layer are integrated.

8. The acoustic wave device according to claim 6, wherein the first intermediate layer and the second intermediate layer include a same material.

9. The acoustic wave device according to claim 1, wherein the excitation electrode is an IDT electrode.

10. The acoustic wave device according to claim 1, wherein the excitation electrode is an upper electrode, and a lower electrode is provided on a major surface of the piezoelectric film on an opposite side to a major surface on which the excitation electrode is provided.

11. The acoustic wave device according to claim 1, wherein
the major surface of the first layer includes a plurality of protrusions that protrude from the major surface of the first layer toward the cavity; and
the plurality of protrusions include protrusions with different heights.

12. The acoustic wave device according to claim 1, wherein
the major surface of the first layer includes a plurality of protrusions that protrude from the major surface of the first layer toward the cavity; and
adjacent ones of the plurality of protrusions are provided with a predetermined distance from each other.

13. The acoustic wave device according to claim 1, wherein
the major surface of the first layer includes a plurality of protrusions that protrude from the major surface of the first layer toward the cavity; and
the plurality of protrusions include end portions pointed on a cavity side.

14. The acoustic wave device according to claim 9, wherein
the major surface of the first layer includes a plurality of protrusions that protrude from the major surface of the first layer toward the cavity;
the IDT electrode includes:
a first busbar and a second busbar facing each other;
a plurality of first electrode fingers including base ends connected to the first busbar; and
a plurality of second electrode fingers including base ends are connected to the second busbar; and
when a region where the plurality of first electrode fingers and the plurality of second electrode fingers overlap each other, when viewed in a direction in which the plurality of first electrode fingers and the plurality of second electrode fingers are arranged, is defined as an intersecting region, the plurality of protrusions are not provided in a location that overlaps the intersecting region and the plurality of protrusions are provided in a location that does not overlap the intersecting region in plan view in a stacking direction of the support substrate and the piezoelectric film.

15. The acoustic wave device according to claim 1, wherein the support substrate is made of silicon.

16. The acoustic wave device according to claim 1, wherein the piezoelectric film is made of piezoelectric single crystal.

17. The acoustic wave device according to claim 6, wherein the first intermediate layer and the second intermediate layer are integrally formed of silicon oxide.

18. The acoustic wave device according to claim 1, wherein the surface roughness of the major surface of the first layer and the surface roughness of the major surface of the second layer is greater than or equal to about 0.5 nm.

19. The acoustic wave device according to claim 1, wherein the surface roughness of the major surface of the first layer and the surface roughness of the major surface of the second layer is greater than or equal to about 1.0 nm.

20. The acoustic wave device according to claim 1, wherein an upper limit of the surface roughness of the major surface of the first layer and the surface roughness of the major surface of the second layer does not exceed a film thickness of the first intermediate layer or the second intermediate layer.
